(19) United States
(12) Patent Application Publication
(10) Pub. No.: US 2026/0271229 A1
(43) Pub. Date: Sep. 10, 2026

(54) A COOLING ARRANGEMENT FOR AN ELECTRONIC DEVICE

(71) Applicant: Telefonaktiebolaget LM Ericsson (publ), Stockholm (SE)

(72) Inventors: Kristian LINDSKOG, Sollentuna (SE); Stevin VAN WYK, Taby (SE); Georg HELLSTRÖM, Stockholm (SE)

(21) Appl. No.: 19/162,328

(22) PCT Filed: Mar. 7, 2023
(86) PCT No.: PCT/SE2023/050204

§ 371 Date: Sep. 4, 2025

(51) Int. Cl. H05K 7/20; H05K 1/02; H05K 7/14

(52) U.S. Cl. CPC H05K 7/20281; H05K 1/021; H05K 7/1427; H05K 7/20272; H05K 2201/064

(57) ABSTRACT

A cooling arrangement (1) for an electronic device (2) comprising a circuit board (3), said cooling arrangement (1) comprising a housing. The housing comprises: a first housing member (4) and a second housing member (5), said first (4) and second (5) housing members jointly defining an inner cavity (6) for accommodating said circuit board (3). The first housing member (4) is provided with external heat transfer fins (14) protruding from an outside of the housing. The cooling arrangement (1) further comprises a first plate (7) sandwiched between an inner surface of the first housing member (4) and the circuit board (3). The first plate (7) and/or said first housing member (4) are provided with one or more first recesses such that at least one first fluid channel (8) is defined by the first plate (7) and the inner surface of the first housing member (4). Also, the cooling arrangement (1) comprises a pump (9) configured to circulate a heat transfer liquid through at least the one or more first fluid channels (8).

### TECHNICAL FIELD

The present invention relates to a cooling arrangement for an electronic device, such as an electronic device of a telecommunications network.

### BACKGROUND OF THE INVENTION

Electronic devices for telecommunication networks may be mounted on top of buildings, on masts, or in rural areas. The electronic devices are thus difficult to access for maintenance and repair. Electronics in the electronic device generate heat during use and thus may need cooling to operate. Some electronic devices employ cooling systems. One example of a cooling system is a pumped liquid cooling system where heat is moved from hot components to an externally facing heat sink using pumped liquid. Other cooling systems make use of heat pipes or vapour chambers to move heat. Heat pipes may require complex routing of the heat pipes and cooling depends on the size of the heat pipe. Some cooling systems use a thermosiphon cooling loop for moving heat from electronic components to a heat exchanger of the base station. Thermosiphon loops are difficult to design for varying heating conditions and varying surrounding temperatures. Also, thermosiphon loops must typically be properly oriented to enable proper operation. Under poor operating conditions thermosiphon loops may fail, for example due to dry out in the thermosiphon preventing circulation of coolant.

Accordingly, it is challenging to design a small and robust cooling system for an electronic device.

Electronic devices often comprise a housing made of cast metal. Such housings are thick and heavy, thus increasing carbon footprint both at manufacturing of the housing and at subsequent handling and transport of the electronic device.

An object of the present disclosure is to provide an improved cooling arrangement suitable for use in an electronic device, such as in an electronic device of a telecommunications network.

### SUMMARY OF THE INVENTION

According to a first aspect, these and other objects are achieved by a cooling arrangement for an electronic device comprising a circuit board. The cooling arrangement comprises a housing comprising a first housing member and a second housing member. The first and second housing members jointly define an inner cavity for accommodating said circuit board. The first housing member is provided with external heat transfer fins protruding from an outside of the housing. The cooling arrangement further comprises a first plate sandwiched between an inner surface of the first housing member and the circuit board. The first plate and/or the first housing member is provided with one or more first recesses such that at least one first fluid channel is defined by the first plate and the inner surface of the first housing member. Further, the cooling arrangement comprises a pump configured to circulate a heat transfer liquid through at least the one or more first fluid channels.

In use, the heat generating components of the electronic device generate heat which needs to be transported away from the heat generating components to avoid overheating and malfunction. The housing protects the electronic device from environmental loads, such as rain and wind, ensuring the electronic device will continue to work despite being mounted outdoors. The heat transfer fins on the outside of the housing provide an increased surface area for dissipating heat to surrounding air. The first plate together with the first housing member defines fluid channels. The heat transfer liquid is circulated through the first fluid channels by the pump, and the heat transfer liquid thereby moves heat away from where it is generated and spreads it over a larger portion of the first housing member, in a controlled manner, wherein the heat of the heat transfer liquid is conducted to surrounding air via the housing and or the heat transfer fins. The channels enable improved control of where the heat transfer liquid flows, such that a lot of heat to can be efficiently removed from one or more particular locations of the circuit board where heat generating components are situated. The cooling arrangement can easily be adapted to different circuit board designs by providing a differently shaped first plate providing differently routed first fluid channels.

The pump may be an electrohydrodynamic pump. An advantage of using an electrohydrodynamic pump is that is has no moving parts and thus provides a robust pump requiring less maintenance.

The cooling arrangement may further comprise one or more heat sinks extending through respective openings in the first plate such that the heat sinks extend from the circuit board into the first fluid channel, wherein the heat sink seals to the first plate at the respective opening in the first plate.

The first plate is easy to shape and flexible such that it allows for slight variations in size and general fit and positioning of the circuit board and the first and second housing members. The heat sink enables efficient conduction of heat from individual heat generating components of the circuit board to the heat transfer liquid. Since the heat sinks seal to the first plate at each opening, heat transfer liquid is prevented from leaking from the first fluid conduits to the other side of the first plate where the heat transfer liquid would risk damaging components of the circuit board.

The first plate may be made of sheet material, thereby providing a light and thin structure with low thermal resistance.

The first plate may be made of metal, such as aluminum. Metal materials are good conductors of heat, thus enabling heat transfer directly from components through the first plate and to the heat transfer liquid, without use of heat sinks extending into the heat transfer liquid.

The cooling arrangement may further comprise a second plate sandwiched between the first plate and the circuit board, wherein the first plate and/or the second plate comprises one or more second recesses configured such that at least one second fluid channel is formed between the first plate and the second plate, and wherein the pump is further configured to circulate the heat transfer liquid through at least the one or more second fluid channels.

The provision of second fluid channels between the first plate and the second plate enables additional control of where heat can be picked up from the circuit board. The second plate enables prevents the heat transfer liquid from reaching the circuit board. The second plate may be made of metal. The metal material enables improved conduction of heat through the second plate.

The first plate may be provided with one or more openings providing fluid communication between the at least one first fluid channels and the at least one second fluid channels, such that heat transfer liquid is able to flow between the at least one first fluid channel and the at least one second fluid channel upon being pumped by the pump.

The openings between the at least one first fluid channel and the at least one second fluid channel enables routing of the flow of heat transfer liquid between the first and second fluid channels. Heat transfer liquid can thereby be routed in a single flow loop making use of both the at least one first fluid channel and the at least one second fluid channel, or it can be routed back and forth between first and second fluid channels, thereby allowing for a more complex three-dimensional routing of heat transfer liquid to cater for space constraints inside the housing, thereby allowing a more compact design of the housing.

The heat transfer fins may comprise a corrugated sheet metal structure defining outer ridges and inner ridges of the sheet metal structure, said inner ridges being attached to the first housing member and said outer ridges facing away from the first housing member.

The sheet metal structure conducts heat energy from the first housing member and the corrugated nature of the sheet metal cooling structure provides an increased surface area for emitting heat to surrounding air. The corrugated structure may be provided by plastically deforming a piece of sheet metal using a press tool.

The cooling arrangement may further comprise at least one outer fluid conduit attached to at least some of said outer ridges of the sheet metal structure, said outer fluid conduit being fluidly connected to the at least one first fluid channel or to the at least one second fluid channel and/or to the pump such that the pump in use circulates the heat transfer liquid also through the at least one outer fluid conduit.

The outer fluid conduit enables fluid to be routed between to different portions of the housing externally of the housing, thus mitigating any need of additional channels within the housing for recirculation of heat transfer liquid, hence enabling more freedom of choosing how the first and second fluid channels extend inside the housing. By attaching the outer fluid conduit to the outer ridges of the external heat transfer fins, heat from heat transfer liquid inside the outer fluid conduit is conducted to the external heat transfer fins also in the contact between the outer fluid conduit and the sheet metal structure, thus increasing the area of the sheet metal structure receiving heat. The heat received by the sheet metal structure is dissipated to surrounding air.

The at least one outer fluid conduit may comprise a first end and a second end, said first end being directly connected to the pump and said second end being connected either to one of the at least one first fluid channels or to one of the at least one second fluid channels.

The at least one outer fluid conduit may have a hollow elongate cross-sectional profile.

The cooling arrangement may further comprise a sealing member provided at adjacent edge portions of the first and second housing members for sealing between the housing members, said sealing member having an H-shaped cross-sectional profile defining two opposing recesses respectively receiving the first and second housing members.

Each one of the opposing recesses of the sealing member may comprise opposing side surfaces connected by a respective bottom surface, wherein at least one of the opposing side surfaces is provided with an elastic sealing element protruding into the respective recess.

Upon insertion of the first and second housing members into the opposing recesses, the elastic sealing element is compressed laterally to the insertion direction of the respective housing member. Since the sealing elements are compressed laterally to the insertion direction, the sealing elements will not bias the first and second housing members away from each other, and the sealing effect thus is not dependent on a high compressive force forcing the first and second housing members towards each other.

The cooling arrangement may further comprise a plurality of clamping members configured to attach to the housing and provide a clamping force forcing the first and second housing members towards each other.

According to a second aspect of the present disclosure, these and other objects are also achieved by an electronic device comprising the cooling arrangement according to any one of the examples discussed above, and the circuit board.

The electronic device may be a base station for a mobile communications network.

### BRIEF DESCRIPTION OF THE DRAWINGS

The appended figures are all schematic illustrations, not drawn to measure. Dotted patterns indicated presence of heat transfer liquid.

FIG. 1a shows a side view of a first embodiment of a cooling arrangement comprising first fluid channels.

FIG. 1b shows a top view of the cooling arrangement also shown in FIG. 1a.

FIG. 2a shows a side view of a second embodiment of a cooling arrangement similar to the cooling arrangement of FIGS. 1a and 1b but further comprising cooling fins extending from the circuit board and into the first fluid channels.

FIG. 2b shows a top view of the cooling arrangement also shown in FIG. 2a.

FIG. 3a shows a side view of a third embodiment of a cooling arrangement similar to the cooling arrangement of FIGS. 1a and 1b but further comprising a second fluid channel, wherein the pump is configured to separately circulate heat transfer liquid through the first fluid channel and the second fluid channel, respectively.

FIG. 3b shows a top view of the cooling arrangement also shown in FIG. 3a.

FIG. 4a shows a side view of a fourth embodiment of a cooling arrangement similar to the cooling arrangement of FIGS. 3a and 3b but comprising holes fluidly connecting the first fluid channels and the second fluid channels, wherein the pump is configured to circulate heat transfer liquid from the first fluid channel through one of the holes to the second fluid channel, and then back to the first fluid channel through a second one of the holes.

FIG. 4b shows a top view of the cooling arrangement also shown in FIG. 4a.

FIG. 5a shows a side view of a fifth embodiment of the cooling arrangement, similar to the embodiment of FIGS. 2a and 2b but further comprising an outer fluid conduit through which the heat transfer liquid is circulated. The outer fluid conduit could also be used in any other embodiment of the cooling arrangement.

FIG. 5b shows a top view of the cooling arrangement also shown in FIG. 5a.

FIG. 6a shows a side view of a sixth embodiment of a cooling arrangement similar to the embodiment shown in FIGS. 5a and 5b but also provided with a second fluid channel fluidly connected to the first fluid channel via holes.

FIG. 7 shows a cross-section of an embodiment of the outer conduit used in the embodiments of FIGS. 5a, 5b, 6a and 6b.

FIG. 8 shows an enlarged detail view of a cross-section of the sealing member positioned between the first housing member and the second housing member.

It should be understood that all reference numerals are not repeated in all figures for a similar component re-used in multiple embodiments, since the component and its reference numeral can readily be identified in other figures.

### DETAILED DESCRIPTION OF PREFERRED EMBODIMENTS

Embodiments of the present disclosure will hereinafter be described with reference to the appended drawings.

The cooling arrangement 1 discussed below is shown assembled into an electronic device 2 comprising a circuit board 3. The electronic device 2 is an electronic device 2 of a telecommunications network, but in may alternatively be any other electronic device 2.

The cooling arrangement 1 may be filled with a heat transfer liquid at manufacturing of the cooling arrangement 1, or it may be filled with heat transfer liquid upon installation. In the figured, the heat transfer liquid is indicated with dotted patterns.

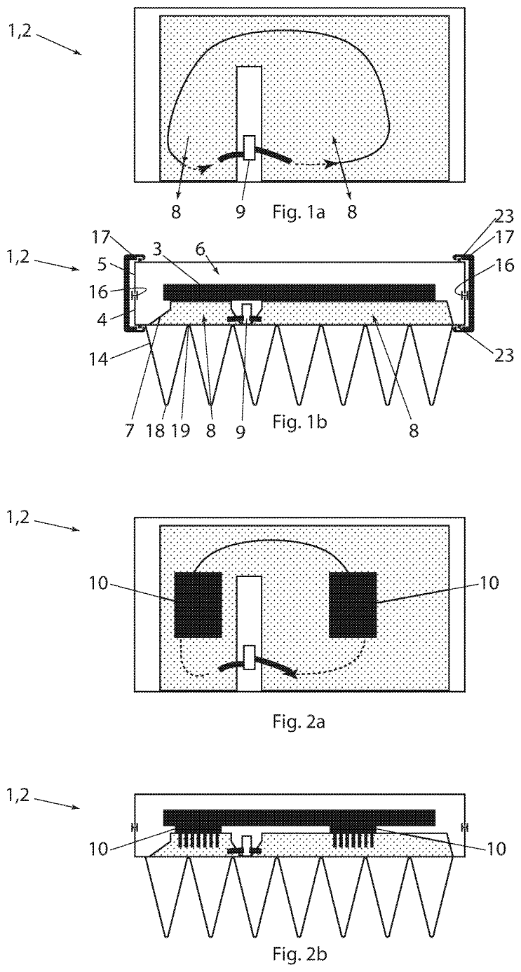

A basic embodiment of the cooling arrangement 1 is shown in FIGS. 1a and 1b. The cooling arrangement 1 comprises a housing comprising a first housing member 4 and a second housing member 5. The first 4 and second 5 housing members jointly define an inner cavity 6 for accommodating the circuit board 3.

The first housing member 4 and the second housing member 5 are made of any suitable material, preferably a material allowing for good heat conduction/low thermal insulation, such as metal, graphite, or a very thin material. In the illustrated embodiments, the housing members 4,5, are made of aluminum sheet metal, but in other embodiments any other suitable material may be used, such as steel or plastic. Aluminum is preferable due to its good heat conductive properties.

The first 4 and second 5 housing members may be made in any other suitable way, such as by molding, or by joining multiple components. For example, inner geometries of the respective housing member 4, 5 may be produced by molding and subsequently joined to a respective outer housing part produced by plastically deforming sheet material, such as aluminum.

Sheet material parts have lower weight and better heat conduction than thicker molded parts. Further, sheet metal has less porosity than molded metal and thus may be preferable to form a thin housing due to a decreased risk of through voids. Parts of the housing members 4, 5 may be joined by brazing or by any other suitable method of manufacturing allowing heat conduction.

The first housing member 4 is provided with external heat transfer fins 14 protruding from an outside of the housing.

The cooling arrangement 1 further comprises a first plate 7 sandwiched between/positioned between, an inner surface of the first housing member 4 and the circuit board 3. The first plate 7 and/or the first housing member 4 is provided with one or more first recesses such that at least one first fluid channel 8 is defined by the first plate 7 and the inner surface of the first housing member 4.

The specific layout of the fluid channels is typically adapted to fit with the layout of the heat generating components of the circuit board 3, such that efficient cooling of heat generating components is enabled. Alternatively, the circuit board layout is adapted to fit with the layout of the fluid channels of the cooling arrangement 1. Accordingly, the illustrated fluid channel layouts and the illustrated number of fluid channels are merely examples, and can in other embodiments be varied, for example depending on the circuit board 3 layout, the position of the pump (described below), etc. Fluid may be routed through a series of fluidly connected channels or may be routed for parallel flows through multiple fluid channels, as needed. This reasoning also applies to the second fluid channels 12 described below.

The cooling arrangement 1 further comprises a pump 9 configured to circulate a heat transfer liquid through at least the one or more first fluid channels 8. In all embodiments shown in the appended figures, the pump 9 is an electrohydrodynamic pump, but it may alternatively in other embodiments be any other suitable type of pump 9. Also, more than one pump 9 may be provided, for redundancy, or to work in parallel with each other to each circulate heat transfer fluid through different ones of the fluid channels 8, 12.

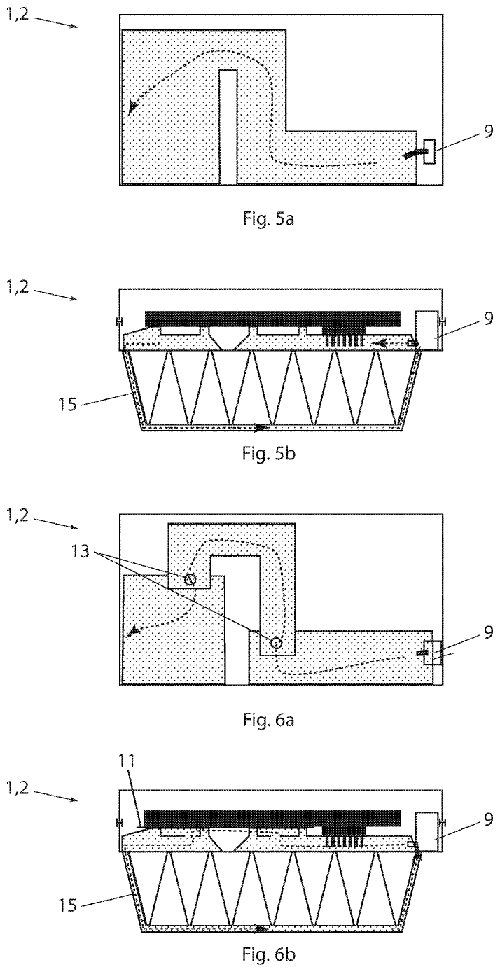

In some embodiments, such as the embodiments shown in FIGS. 2a, 2b, 5a, and 5b, the first plate 7 is made of plastic. In other embodiments, the first plate 7 may be made of any other suitable material, such as metal, for example aluminum.

In some embodiments, such as the embodiments shown in FIGS. 2a, 2b, 5a, and 5b, the cooling arrangement 1 may comprise one or more heat sinks 10 extending through respective openings 13 in the first plate 7 such that the heat sinks 10 extend from the circuit board 3 into the first fluid channel 7. Each heat sink 10 seals to the first plate 7 at the respective opening 13 in the first plate 7. The use of such heat sinks 10 is especially advantageous when the first plate 7 is made of plastic, since plastic is not a good conductor of heat.

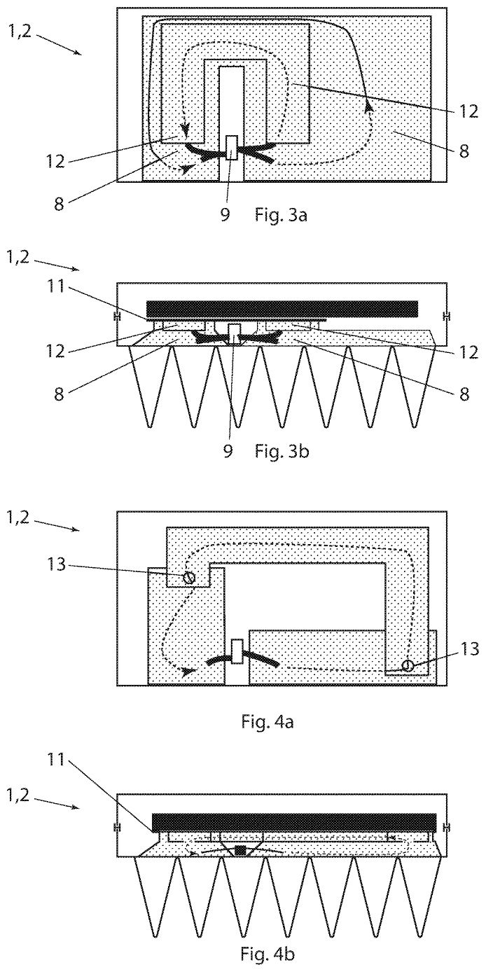

In some embodiments, such as in the embodiments shown in FIGS. 3a, 3b, 6a, and 6b, the cooling arrangement 1 further comprises a metal plate 11 sandwiched between/positioned between, the first plate 7 and the circuit board 3. The first plate 7 and/or the metal plate 11 comprises one or more second recesses configured such that at least one second fluid channel 12 is formed between the first plate 7 and the metal plate 11. The pump 9 is further configured to circulate the heat transfer liquid through at least the one or more second fluid channels 12. In other embodiments, an additional pump may be provided to circulate the heat transfer liquid through the second fluid channels 12. The pump 9 may either be directly fluidly connected to the second fluid channel(s) 12 by fluid conduits, such as hoses, or the pump 9 may be fluidly connected to the second fluid channel(s) 12 via the first fluid channel(s), possibly also making use of an outer fluid conduit 15, such as the one described with reference to FIGS. 6a and 6b.

In embodiments with both first 8 and second 12 fluid channels, the first plate 7 may be provided with one or more openings 13 providing fluid communication between the at least one first fluid channels 8 and the at least one second fluid channels 12, such that heat transfer fluid is able to flow between the at least one first fluid channel 8 and the at least one second fluid channel 12 upon being pumped by the pump 9. Such embodiments are shown in FIGS. 4a, 4b, 6a, and 6b.

The heat transfer fins 14 may comprise a corrugated sheet metal structure. The corrugated sheet metal structure may define outer ridges 18 and inner ridges 19 (see FIG. 1b) of the corrugated sheet metal. As shown in FIGS. 1b, 2b, 3b, 4b, 5b and 6b, the inner ridges are attached to the first housing member 4 and the outer ridges facing away from the first housing member 4. In other embodiments, the heat transfer fins 14 may instead be manufactured in any other suitable way, such as by being molded, or by being formed by sheet metal parts brazed together to form the heat transfer fins 14. The heat transfer fins 14 may also be integrally molded with the first housing member 4.

As shown in FIGS. 5b, and 6b, the cooling arrangement 1 may further comprise at least one outer fluid conduit 15 attached to the heat transfer fins 14, for example attached to at least some of said outer ridges 18 of the corrugated sheet metal structure. The attachment between the heat transfer fins 14 and the outer fluid conduit should be made to promote efficient heat conduction from the first housing to the heat transfer fins 14, such as by brazing or welding.

The outer fluid conduit is fluidly connected to the at least one first fluid channel 8 or to the at least one second fluid channel 12 and/or to the pump 9 such that the pump 9 in use circulates the heat transfer liquid also through the at least one outer fluid conduit 15.

The outer fluid conduit 15 not only enables fluid transport between different locations on the housing, but also increases the surface area in contact with the heat transfer fins 14 for conduction of heat from the heat transfer liquid.

In some embodiments, such as the embodiments shown in in FIGS. 4a, 4b, 5a and 5b, the at least one outer fluid conduit 15 comprises a first end and a second end, said first end being directly connected to the pump 9 and said second end being connected to the at least one first fluid channel 8. In other embodiments, the second end may alternatively be connected to the at least one second fluid channel 12.

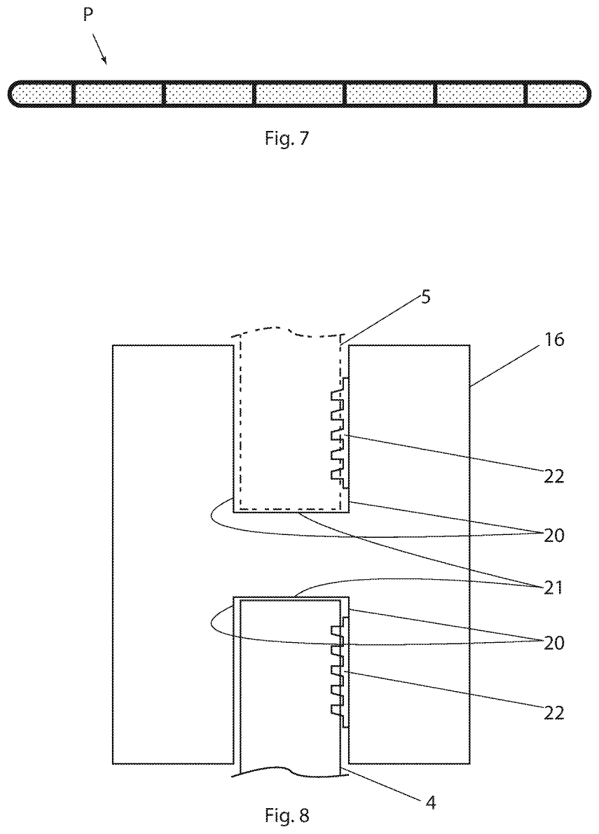

As shown in FIG. 7, the at least one outer fluid conduit 15 has a hollow elongate cross-sectional profile P. In other embodiments, the outer fluid conduit 15 may alternatively have any other suitable shape. Also, more than one outer fluid conduit 15 may be provided. Each end of the outer fluid conduit 15 may be provided with a respective header. The header gathers one or more internal channels of the outer fluid channel and is adapted for connection to the housing and/or to the pump 9. Alternatively, the outer fluid conduit ends directly in the housing or the pump 9 without use of headers.

In the illustrated embodiments, the pump 9 is provided within said inner cavity 6 of the housing. This protects the pump 9. In other embodiments, the pump 9 may be provided on the outside of the housing.

In the illustrated embodiments, the cooling arrangement 1 further comprises a sealing member 16 provided at adjacent edge portions of the first 4 and second 5 housing members for sealing between the housing members 4, 5. As shown in the enlarged details view of FIG. 8, the sealing member has an H-shaped cross-sectional profile defining two opposing recesses respectively receiving the first 4 and second 5 housing members. The H-shaped profile guides the edge portions and thus improves rigidity of the housing.

The sealing member 16 extends all around the circumference of the adjacent edge portions of the first 4 and second 5 housing members.

Each one of the opposing recesses of the sealing member 16 comprises opposing side surfaces 20 connected by a respective bottom surface 21, wherein at least one of the opposing side surfaces 20 is provided with an elastic sealing element 22 protruding into the respective recess. Upon insertion of the first 4 and second 5 housing members into the opposing recesses, the elastic sealing element 22 is compressed laterally to the insertion direction of the respective housing member 4, 5. Since the sealing elements 22 are compressed laterally to the insertion direction, the sealing elements 22 will not bias the first 4 and second 5 housing members away from each other, and the sealing effect thus is not dependent on a compressive force forcing the first 4 and second 5 housing members towards each other.

In other embodiments, any other suitable design of the sealing member 16 could alternatively be used instead, such as an O-ring or gasket fitted between respective flanges of the first 4 and second 5 housing members. In such embodiments, mechanical fasteners, such as screws, may be used to force the flanges towards each other.

A plurality of clamping members 17 may be provided, said clamping members 17 being configured to attach to the housing and provide a clamping force forcing the first 4 and second 5 housing members towards each other against the sealing member 16. FIG. 1b shows as example of such clamping members 17. The clamping members 17 may snap-lock onto the housing, or they may be configured to slide into engagement with the housing in a direction along a portion of the circumferential interface between the first and second housing members, locking onto ridges 23 or recesses provided on the housing.

As mentioned above, it is proposed to provide the cooling arrangement 1 as part of an electronic device 2 of a telecommunications network. In other embodiments, any other type of electronic device 2 could be provided with the cooling arrangement 1.

Table of reference numerals

| | |
|---|---|
| 1 | cooling arrangement |
| 2 | electronic device |
| 3 | circuit board |
| 4 | first housing member |
| 5 | second housing member |
| 6 | inner cavity |
| 7 | first plate |
| 8 | first fluid channel(s) |
| 9 | pump |
| 10 | heat sink(s) |
| 11 | metal plate |
| 12 | second fluid channel(s) |
| 13 | opening(s) between first and second fluid channel |
| 14 | heat transfer fins |
| 15 | outer fluid conduit |
| 16 | sealing member |
| 17 | clamping member |
| 18 | outer ridge |
| 19 | inner ridge |
| 20 | side surfaces |
| 21 | bottom surface |
| 22 | elastic sealing element |
| 23 | ridges of housing |
| P | cross-sectional profile of outer fluid conduit |

1. A cooling arrangement for an electronic device comprising a circuit board, said cooling arrangement comprising a housing, said housing comprising:
a first housing member and a second housing member, said first and second housing members jointly defining an inner cavity for accommodating said circuit board,
said first housing member being provided with external heat transfer fins protruding from an outside of the housing,
said cooling arrangement further comprising a first plate sandwiched between an inner surface of the first housing member and the circuit board,
said first plate and/or said first housing member being provided with one or more first recesses first housing member such that at least one first fluid channel is defined by the first plate and the inner surface of the first housing member, and
said cooling arrangement further comprising a pump configured to circulate a heat transfer liquid through at least the one or more first fluid channels.

2. The cooling arrangement according to claim 1, further comprising one or more heat sinks extending through respective openings in the first plate such that the heat sinks extend from the circuit board into the first fluid channel, wherein the heat sink seals to the first plate at the respective opening in the first plate.

3. The cooling arrangement according to claim 1, wherein the first plate is made of sheet material.

4. The cooling arrangement according to claim 1, wherein the first plate is made of metal.

5. The cooling arrangement according to claim 1, further comprising a second plate sandwiched between the first plate and the circuit board,
wherein the first plate and/or the second plate comprises one or more second recesses configured such that at least one second fluid channel is formed between the first plate and the second plate, and
wherein the pump is further configured to circulate the heat transfer liquid through at least the one or more second fluid channels.

6. The cooling arrangement according to claim 5, wherein the second plate is made of metal.

7. The cooling arrangement according to claim 5, wherein the first plate is provided with one or more openings providing fluid communication between the at least one first fluid channels and the at least one second fluid channels, such that heat transfer liquid is able to flow between the at least one first fluid channel and the at least one second fluid channel upon being pumped by the pump.

8. The cooling arrangement according to claim 1, wherein the heat transfer fins comprise a corrugated sheet metal structure defining outer ridges and inner ridges of the sheet metal structure, said inner ridges being attached to the first housing member and said outer ridges facing away from the first housing member.

9. The cooling arrangement according to claim 8, further comprising at least one outer fluid conduit attached to at least some of said outer ridges of the sheet metal structure, said outer fluid conduit being fluidly connected to the at least one first fluid channel or to the at least one second fluid channel and/or to the pump such that the pump in use circulates the heat transfer liquid also through the at least one outer fluid conduit.

10. The cooling arrangement according to claim 9, wherein the at least one outer fluid conduit comprises a first end and a second end, said first end being directly connected to the pump and said second end being connected either to one of the at least one first fluid channels or to one of the at least one second fluid channels.

11. The cooling arrangement according to claim 9, wherein the at least one outer fluid conduit has a hollow elongate cross-sectional profile.

12. The cooling arrangement according to claim 1, further comprising a sealing member provided at adjacent edge portions of the first and second housing members for sealing between the housing members, said sealing member having an H-shaped cross-sectional profile defining two opposing recesses respectively receiving the first and second housing members.

13. The cooling arrangement according to claim 12, wherein each one of the opposing recesses of the sealing member comprises opposing side surfaces connected by a respective bottom surface, wherein at least one of the opposing side surfaces is provided with an elastic sealing element protruding into the respective recess.

14. The cooling arrangement according to claim 12, further comprising a plurality of clamping members configured to attach to the housing and provide a clamping force forcing the first and second housing members towards each other.

15. The cooling arrangement according to claim 1, wherein the pump is an electrohydrodynamic pump.

16. An electronic device of a telecommunications network, said electronic device comprising the cooling arrangement according to claim 1, and a circuit board.
